(19) United States
(12) Patent Application Publication
(10) Pub. No.: US 2026/0214879 A1
(43) Pub. Date: Jul. 23, 2026

(54) MEMORY DEVICE USING SEMICONDUCTOR ELEMENT

(71) Applicant: Unisantis Electronics Singapore Pte. Ltd., Singapore (SG)

(72) Inventors: Koji SAKUI, Tokyo (JP); Nozomu Harada, Tokyo (JP); Takashi Ohsawa, Tokyo (JP)

(21) Appl. No.: 19/444,714

(22) Filed: Jan. 9, 2026

(30) Foreign Application Priority Data
Jan. 20, 2025 (JP) 2025-007709

(51) Int. Cl. H10B 12/00; G11C 11/404

(52) U.S. Cl. CPC H10B 12/20; G11C 11/404

(57) ABSTRACT

A plurality of dynamic flash memory cells are arranged in a matrix shape on a substrate, first and second dynamic flash memory cells overlap each other in a vertical or horizontal direction of the substrate, voltages applied to a selection gate line, a plate line, and a source line which are common to the first and second dynamic flash memory cells, an independent first bit line, and an independent second bit line are controlled to perform a data erase operation on the first and second dynamic flash memory cells, a data write operation on one or both of the first and second dynamic flash memory cells, a data write-protect operation on another or both of the first and second dynamic flash memory cells, and a data read operation on one or both of the first and second dynamic flash memory cells.

### CROSS-REFERENCE TO RELATED APPLICATIONS

This application claims priority to JP2025-007709, filed January 20, 2025, the entire content of which is incorporated herein by reference.

### BACKGROUND OF THE INVENTION

### 1. Field of the Invention

The present invention relates to a memory device using a semiconductor element.

### 2. Description of the Related Art

Today, in technical development of large scale integration (LSI), there is a demand for higher integration and higher performance of memory elements.

The integration of the memory elements is being increased and the performance of the memory elements is being improved. There are, for example, the following memory elements: a dynamic random access memory (DRAM) that uses a surrounding gate transistor (SGT) as a selection transistor to which a capacitor is connected (for the SGT, see Japanese Unexamined Patent Application Publication No. 2-188966, and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991); for the DRAM, see, for example, H. Chung, H. Kim, H. Kim, K. Kim, S. Kim, K. W. Song, J. Kim, Y.C. Oh, Y. Hwang, H. Hong, G. Jin, and C. Chung: "4F2 DRAM Cell with Vertical Pillar Transistor (VPT)", 2011 Proceeding of the European Solid-State Device Research Conference, (2011)); a phase change memory (PCM) to which a resistance change element is connected (see, for example, H. S. Philip Wong, S. Raoux, S. Kim, Jiale Liang, J. R. Reifenberg, B. Rajendran, M. Asheghi and K. E. Goodson: "Phase Change Memory", Proceeding of IEEE, Vol. 98, No 12, December, pp. 2201-2227 (2010)); a resistive random access memory (RRAM, see, for example, K. Tsunoda, K .Kinoshita, H. Noshiro, Y. Yamazaki, T. Iizuka, Y. Ito, A. Takahashi, A. Okano, Y. Sato, T. Fukano, M. Aoki, and Y. Sugiyama : "Low Power and high Speed Switching of Ti-doped NiO ReRAM under the Unipolar Voltage Source of less than 3V", IEDM (2007)); and a magneto-resistive random access memory (MRAM) that changes the resistance by changing the direction of magnetic spin with a current (see, for example, W. Kang, L. Zhang, J. Klein, Y. Zhang, D. Ravelosona, and W. Zhao: "Reconfigurable Codesign of STT-MRAM Under Process Variations in Deeply Scaled Technology", IEEE Transaction on Electron Devices, pp. 1-9 (2015)).

There also is, for example, a capacitorless DRAM cell including a single metal oxide semiconductor (MOS) transistor (see Japanese Unexamined Patent Application Publication No. 3-171768, M. G. Ertosun, K. Lim, C. Park, J. Oh, P. Kirsch, and K. C. Saraswat: "Novel Capacitorless Single-Transistor Charge-Trap DRAM (1T CT DRAM) Utilizing Electron", IEEE Electron Device Letter, Vol. 31, No. 5, pp. 405-407 (2010), J. Wan, L. Rojer, A. Zaslavsky, and S. Critoloveanu: "A Compact Capacitor-Less High-Speed DRAM Using Field Effect-Controlled Charge Regeneration", Electron Device Letters, Vol. 35, No. 2, pp. 179-181 (2012), T. Ohsawa, K. Fujita, T. Higashi, Y. Iwata, T. Kajiyama, Y. Asao, and K. Sunouchi: "Memory design using a one-transistor gain cell on SOI", IEEE JSSC, vol. 37, No. 11, pp. 1510-1522 (2002), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: "Floating Body RAM Technology and its Scalability to 32nm Node and Beyond", IEEE IEDM (2006), and E. Yoshida: "A Capacitorless 1T-DRAM Technology Using Gate-Induced Drain-Leakage (GIDL) Current for Low-Power and High-Speed Embedded Memory", IEEE IEDM (2006)). In the DRAM cell including a single MOS transistor, for example, part or the entirety of a positive hole group out of the positive hole group and an electron group generated in a channel by impact ionization due to a current between a source and a drain of an N-channel MOS transistor is held in the channel to write logical storage data "1". Logical storage data "0" is written by discharging the positive hole group from the channel. As memory cells, the memory cell for writing "1" and the memory cell for writing "0" are randomly provided with a shared selection word line. When an ON voltage is applied to the selection word line, a floating body channel voltage of the selection memory cell continuous with this selection word line significantly fluctuates due to capacitive coupling between the gate electrode and the channel. Regarding this memory cell, the following tasks arise: suppressing reduction of an operation margin due to voltage fluctuation of the floating body channel; and reduction of degradation of data retention due to discharging of part of the positive hole group serving as signal charges stored in the channel.

There also is a twin-transistor MOS memory element in which a single memory cell is formed by using two MOS transistors in a silicon on insulator (SOI) layer (see, for example, U.S. Patent Application Publication No. 2008/0137394 A1, U.S. Patent Application Publication No. 2003/0111681 A1, and F. Morishita, H. Noda, I. Hayashi, T. Gyohten, M. Oksmoto, T. Ipposhi, S. Maegawa, K. Dosaka, and K. Arimoto: "Capacitorless Twin-Transistor Random Access Memory (TTRAM) on SOI", IEICE Trans. Electron., Vol. E90-c., No. 4 pp. 765-771 (2007)). In these elements, an N⁺ layer serving as a source or a drain that separates floating body channels of the two MOS transistors is formed so as to be in contact with an insulating layer provided on the substrate side. With this N⁺ layer, the floating body channels of two MOS transistors are electrically isolated. A positive hole group serving as signal charges is stored only in the floating body channel of one of the MOS transistors. The other MOS transistor serves as a switch for reading the positive hole group of the signal stored in the one of the MOS transistors. Also in this memory cell, since the positive hole group serving as the signal charges is stored in the channel of a single MOS transistor, the following task arises as is the case with the above-described memory cell including a single MOS transistor: suppressing reduction of the operation margin; or reduction of degradation of the data retention due to discharging of part of the positive hole group serving as the signal charges stored in the channel.

There also is a capacitorless dynamic flash memory (DFM) cell 111 illustrated in FIGS. 3A, 3B, 3C, and FIG. 3D that includes a MOS transistor (see Japanese Patent No. 7057032 and K. Sakui, and N. Harada, "Dynamic Flash Memory with Dual Gate Surrounding Gate Transistor (SGT)", Proc. IEEE IMW, pp. 72-75(2021)). As illustrated in FIG. 3A, a floating body semiconductor base 102 is provided on an SiO₂ layer 101 of a SOI substrate. An N⁺ layer 103 connected to a source line SL and an N⁺ layer 104 connected to a bit line BL are respectively provided at one end and the other end of the floating body semiconductor base 102. A first gate insulating layer 109a and a second gate insulating layer 109b are also provided. The first gate insulating layer 109a is continuous with the N⁺ layer 103 and covers the floating body semiconductor base 102. The second gate insulating layer 109b is continuous with the N⁺ layer 104 and the first gate insulating layer 109a via a slit insulating film 110 and covers the floating body semiconductor base 102. Also, a first gate conductor layer 105a and a second gate conductor layer 105b are provided. The first gate conductor layer 105a covers the first gate insulating layer 109a and is continuous with a plate line PL. The second gate conductor layer 105b covers the second gate insulating layer 109b and is continuous with a word line WL. The slit insulating film 110 is provided between the first gate conductor layer 105a and the second gate conductor layer 105b. Thus, the memory cell 111 of a DFM is formed. The source line SL and the bit line BL may be respectively connected to the N⁺ layer 104 and the N⁺ layer 103.

As illustrated in FIG. 3A, for example, a zero voltage is applied to the N⁺ layer 103 and a positive voltage is applied to the N⁺ layer 104 so as to cause a first N-channel MOS transistor region including the floating body semiconductor base 102 covered with the first gate conductor layer 105a to operate in a saturation region and cause a second N-channel MOS transistor region including the floating body semiconductor base 102 covered with the second gate conductor layer 105b to operate in a linear region. As a result, no pinch-off point exists in the second N-channel MOS transistor region, and an inversion layer 107b is formed throughout a surface. The inversion layer 107b formed on the lower side of the second gate conductor layer 105b connected to the word line WL operates as a substantial drain of the first N-channel MOS transistor region. As a result, an electric field is maximized in a boundary region of the semiconductor base between the first N-channel MOS transistor region and the second N-channel MOS transistor region, thereby producing impact ionization in this region. Then, as illustrated in FIG. 3B, an electron group out of the electron group and a positive hole group generated by the impact ionization is discharged from the floating body semiconductor base 102, and part or the entirety of a positive hole group 106 is held in the floating body semiconductor base 102 so as to perform a memory write operation. This state is the logical storage data "1".

As illustrated in FIG. 3C, for example, an erase operation is performed by applying a positive voltage to the plate line PL, a zero voltage to the word line WL and the bit line BL, and a negative voltage to the source line SL so as to discharge the positive hole group 106 from the floating body semiconductor base 102. This state is the logical storage data "0". In data reading, a characteristic with which no current flows even when the voltage of the word line WL is increased in reading of the logical storage data "0" as illustrated in FIG. 3D can be obtained by setting a voltage applied to the first gate conductor layer 105a continuous with the plate line PL to be higher than a threshold voltage at the time of the logical storage data "1" and lower than a threshold voltage at the time of logical storage data "0". Due to this characteristic, the operation margin can be significantly increased compared to the case of the capacitorless DRAM cell including a single MOS transistor. In this memory cell, the channels of the first and second N-channel MOS transistor regions using, as the gates, the first gate conductor layer 105a continuous with the plate line PL and the second gate conductor layer 105b continuous with the word line WL are continuous in the floating body semiconductor base 102. Thus, voltage fluctuation of the floating body semiconductor base 102 occurring when a selection pulse voltage is applied to the word line WL is significantly suppressed. This greatly suppresses the reduction of the operation margin which arises the problem in the above-described memory cell or greatly reduces the problem of degradation of data retention due to discharging of part of the positive hole group serving as signal charges stored in the channel. From this time, further improvement of the characteristics is demanded of this memory element.

There also is a known capacitorless dynamic flash memory cell 8 illustrated in FIG. 4 that includes a MOS transistor and three gates (see U.S. Patent Application Publication No. 2023/0186966 A1 and K. Sakui, Y. Li, M. Kakumu, K. Kanazawa, I. Kunishima, Y. Iwata, and N. Harada, "Design Impact on Three Gate Dynamic Flash Memory (3G_DFM) for Long Hole Retention Time and Robust Disturbance Shield", in Memories - Materials, Devices, Circuits and Systems, Elsevier, 4, 100054, pp .1-5, May 2023). A silicon semiconductor pillar (Si pillar) 2 is provided on a substrate 1. The Si pillar 2 includes an N⁺ layer 3a, a P layer 7, and an N⁺ layer 3b in this order from below. The P layer 7 between the N+ layers 3a and 3b serves as a channel region 7a. A first gate insulating layer 4a, a second gate insulating layer 4b, and a third gate insulating layer 4c are provided in this order from below so as to surround the Si pillar 2. A first gate conductor layer 5a is provided so as to surround the first gate insulating layer 4a, a second gate conductor layer 5b is provided so as to surround the second gate insulating layer 4b, and a third gate conductor layer 5c is provided so as to surround the third gate insulating layer 4c. The first gate conductor layer 5a and the second gate conductor layer 5b are isolated from each other by an insulating layer 6a, and the second gate conductor layer 5b and the third gate conductor layer 5c are isolated from each other 3b in this order from below. The P layer 7 between the N⁺ layers 3a and 3b serves as a channel region 7a. A first gate insulating layer 4a, a second gate insulating layer by an insulating layer 6b. Thus, the dynamic flash memory cell including the following layers are formed: the N⁺ layers 3a and 3b; the P layer 7; the first gate insulating layer 4a, the second gate insulating layer 4b, and the third gate insulating layer 4c; and the first gate conductor layer 5a, the second gate conductor layer 5b, and the third gate conductor layer 5c. As a feature of this structure, recombination of the positive hole group stored in the channel region 7a between the N⁺ layers 3a and 3b is significantly suppressed in the N⁺ layers 3a and 3b due to utilization of electrical shielding between the first gate conductor layer 5a and the third gate conductor layer 5c. As a result, the retention of the data "1" is significantly improved. The dynamic flash memory cells may be provided parallel to the substrate 1 so as to laminate a plurality of memory cells in the perpendicular direction. This can increase the degree of integration (see U.S. Patent Application Publication No. 2022/0367681 A1). The first gate conductor layer 5a, the second gate conductor layer 5b, and the third gate conductor layer 5c may be divided (see, for example, U.S. Patent Application Publication No. 2022/0367473 A1 and K. Sakui, and N. Harada, "Read Non-Destructive Dynamic Flash Memory (DFM) with Dual and Double Gates", Extended Abstracts of the 2022 International Conference on Solid State Devices and Materials, pp. 405-406, Sep. 2022).

There also are publications of a capacitorless thyristor RAM including three gates (see W.-C. Chen, H.-T. Lue, M.-Y. Wu, T.-H. Yeh, P.-Y. Du, T.-H. Hsu, C.-C. Hsieh, K.-C. Wang, and C.-Y. Lu, "A 3D Stackable DRAM: Capacitor-less Three-Wordline Gate-Controlled Thyristor (GCT) RAM with >40 μA Current Sensing Window, >1010 Endurance, and 3-second Retention at Room Temperature", in IEEE IEDM (International Electron Devices Meeting), pp. 607-610, Dec. 2022 and W.-C. Chen, H.-T. Lue, T.-H. Hsu, K.-C. Wang, and C.-Y. Lu, "A Simulation Study of Scaling Capability toward 10 nm for the 3D Stackable Gate-Controlled Thyristor (GCT) DRAM Device", in IEEE IMW (International Memory Workshop), pp. 25-28, May 2023). This thyristor memory has an advantage in that a plurality of layers can be laminated so as to reduce an equivalent memory size. However, since the thyristor is used as a reading mechanism, a reading current value is significantly increases and decreases. As a result, power consumption increases.

There also are publications of a 1T1C DRAM cell including a capacitor that can be laminated (see M. Huang, S. Si, Z. He, Y. Zhou, S. Li, H. Wang, J. Liu, D. Xie, M. Yang, K. You, C. Choi, Y. Tang, X. Li, S. Qian, X. Yang, L. Hou, W. Bai, Z. Liu, Y. Tang, Q. Wu, Y. Wang, T. Dou, J. Kim, G.-L. Wang, J. Bai, A. Takao, C. Zhao, A. Yoo, M. Zhou, "A 3D Stackable 1T1C DRAM: Architecture, Process Integration and Circuit Simulation", in IEEE IMW (International Memory Workshop), pp. 29-32, May 2023 and J.W. Han, S.H. Park, M.Y. Jeong, K.S. Lee, K.N. Kim, H.J. Kim, J.C. Shin, S.M. Park, S.H. Shin, S.W. Park, K.S. Lee, J.H. Lee, S.H. Kim, B.C Kim, M.H. Jung, I.Y. Yoon, H. Kim, S.U. Jang, K.J. Park, Y.K. Kim, I.G. Kim, J.H Oh, S.Y. Han, B.S. Kim, B.J. Kuh, and J.M. Park, "Ongoing Evolution of DRAM Scaling via Third Dimension- Vertically Stacked DRAM", in 2023 Symposium on VLSI Technology and Circuits Digest of Technical Papers, TFS1-1, pp. 1-2, Jun. 2023). However, the aspect ratio of the capacitor of the DRAM cell is 50, which is large. Since the area of this capacitor is very large, when the DRAM cell is horizontally disposed, for example, as many as 200 layers are required to be laminated to obtain an equivalent area of an economical memory cell such as existing vertically disposed DRAM cell.

There also is a proposal of lamination of capacitorless DRAM cells each including a single MOS transistor (see U.S. Patent Application Publication No. 2023/0106561 A1). A problem arises with this structure in that, when an ON voltage is applied to the above-described selection word line, a floating body channel voltage of the selection memory cell continuous with this selection word line significantly fluctuates due to capacitive coupling between the gate electrode and the channel. Furthermore, as illustrated in FIG. 1F of U.S. Patent Application Publication No. 2023/0106561 A1, for example, a common floating body FB1 is controlled with two word lines WL0 and WL1. Thus, a problem of selectivity arises. As a countermeasure, a method in which, as illustrated in FIG. 1G, alternate word lines are grounded as shielded lines is indicated. However, there arises a problem with this method in that memory capacity is halved and the cost is doubled.

### SUMMARY OF THE INVENTION

For a dynamic flash memory cell, a memory cell having a smaller effective cell size is to be realized.

In a memory device using a semiconductor element according to the present invention, a plurality of semiconductor memory cells including a first memory cell and a second memory cell are arranged on a substrate. The first memory cell includes a first semiconductor base extending in a first direction parallel to the substrate. The second memory cell includes a second semiconductor base separated from the first semiconductor base in a vertical direction or a horizontal direction. The second semiconductor base overlaps the first semiconductor base in plan view when the second semiconductor base is separated from the first semiconductor base in the vertical direction. The second semiconductor base is at a position overlapping the first semiconductor base in sectional view when the second semiconductor base is separated from the first semiconductor base in the horizontal direction. The memory device includes a first impurity region and a second impurity region respectively continuous with one end and another end of the first semiconductor base, a third impurity region and a fourth impurity region respectively continuous with one end and another end of the second semiconductor base, a first gate insulating layer in contact with a first side surface out of side surfaces of the first semiconductor base facing the second semiconductor base, a second gate insulating layer in contact with a second side surface out of side surfaces of the second semiconductor base facing the first semiconductor base, and one or two first gate conductor layers and one or two second gate conductor layers. Each of the first gate conductor layers and each of the second gate conductor layers are in contact with the first and second gate insulating layers so as to function as the gate conductor layers common to the first memory cell and second memory cell. Each of the first gate conductor layers and each of the second gate conductor layers are arranged in the first direction and isolated from each other. The first to fourth impurity regions and the first and second gate conductor layers are configured such that, when the memory device is controlled so as to apply a voltage to the first to fourth impurity regions and the first and second gate conductor layers, a data write operation, a data write-protect operation, a data erase operation, and a data read operation are performed as follows. In one or both of the first semiconductor base and the second semiconductor base, the data write operation causes a part or an entirety of a positive hole group or an electron group serving as a majority carrier to remain in one or both of the first semiconductor base and the second semiconductor base. During the data write operation, the data write-protect operation prohibits remaining of the part or the entirety of the positive hole group or the electron group in another or both of the first semiconductor base and the second semiconductor base. The data erase operation discharges the remaining positive hole group or the remaining electron group from one or both of the first and second impurity regions and one or both of the third and fourth impurity regions. By using storage data of a data write state or a data erase state in one of the first semiconductor base and the second semiconductor base, the data read operation causes a current to flow through the first semiconductor base or the second semiconductor base or prohibits flowing of the current through the first semiconductor base or the second semiconductor base. The second impurity region is connected to a first bit line, the fourth impurity region is connected to a second bit line, and the first and third impurity regions are connected to a source line.

Preferably, one of the first gate conductor layer and the second gate conductor layer is connected to a first selection gate line and another of the first gate conductor layer and the second gate conductor layer is connected to a plate line, and, when the memory device is controlled so as to apply the voltage to the first and second bit lines, the source line, the plate line, and the first selection gate line, the data erase operation, the data write operation, and the data read operation are performed.

Preferably, in the data write-protect operation, the voltage applied to the first or second bit line and the voltage applied to the source line are identical to each other.

Preferably, the data read operation on the first memory cell connected to the first bit line and the data read operation on the second memory cell connected to the second bit line are performed simultaneously or alternately.

Preferably, the first and second semiconductor bases overlap each other in sectional view of the substrate, and the plate line and the first selection gate line are disposed parallel to the substrate such that the plate line and the selection gate line are perpendicular to the substrate in plan view.

Preferably, the first and second bit lines are disposed perpendicular to the plate line and the first selection gate line in perpendicular sectional view with respect to the substrate.

Preferably, the first and second semiconductor bases overlap each other in plan view of the substrate, and the plate line and the first selection gate line are disposed parallel to the substrate such that the plate line and the selection gate line are perpendicular to the substrate in sectional view.

Preferably, the first and second bit lines are disposed perpendicular to the plate line and the first selection gate line in plan view with respect to the substrate.

Preferably, the first selection gate line includes an isolated second selection gate line and an isolated third selection gate line, In this case, one of the first gate conductor layer and the second gate conductor layer is divided into two gate conductor layers. In this case, one of the divided gate conductor layers is connected to the second selection gate line and another of the divided gate conductor layers is connected to the third selection gate line. In this case, the first gate conductor layer or the second gate conductor layer that has not been divided is connected to the plate line. In this case, the gate conductor layer connected to the second selection gate line and the gate conductor layer connected the third selection gate line are disposed on one side and another side of the gate conductor layer connected to the plate line.

Preferably, a channel length of the gate conductor layer connected to the plate line is greater than a channel length of the gate conductor layer connected to the second selection gate line and a channel length of the gate conductor layer connected to the third selection gate line.

Preferably, the plurality of semiconductor memory cells are arranged in a matrix shape on the substrate to form memory blocks, and a plurality of the memory blocks are selected when at least one of the data write operation, the data erase operation, and the data read operation is performed.

Preferably, when the data write operation or the data read operation is performed in the first semiconductor base, the part or the entirety of the positive hole group or the electron group serving as the majority carrier is collected to the side surface of one of the first gate insulating layer side or the second gate insulating layer side.

Preferably, the first to fourth impurity regions and the first and second gate conductor layers are configured such that the data write operation, the data write-protect operation, the data erase operation, and the data read operation are performed as follows. The data write operation causes the part or the entirety of the positive hole group or the electron group serving as the majority carrier to remain in the first or second semiconductor base. The positive hole group or the electron group is generated by impact ionization due to a current flowed through the one of the first and second semiconductor bases or a gate induced drain leakage current. The data write-protect operation does not cause the impact ionization or does not allow flowing of the gate induced drain leakage current in another of the first and second semiconductor bases during the data write operation so as to prohibit remaining of the part or the entirety of the positive hole group or the electron group serving as the majority carrier in the first or second semiconductor base. The data erase operation discharges the remaining positive hole group or the remaining electron group from one or both of the first and second impurity regions and one or both of the third and fourth impurity regions. By using the storage data of the data write state or the data erase state of one of the first and second semiconductor bases, the data read operation causes the current to flow through the first or second semiconductor base or prohibits flowing of the current through the first or second semiconductor base.

### BRIEF DESCRIPTION OF THE DRAWINGS

FIG. 1A illustrates a structure of memory cells according to a first embodiment;

FIGS. 1BA, 1BB, and FIG. 1BC illustrate the structure of the memory cells according to the first embodiment;

FIG. 1C illustrates a structure of the memory cells according to the first embodiment;

FIG. 1D illustrates a structure of the memory cells according to the first embodiment;

FIG. 1E illustrates a structure of the memory cells according to the first embodiment;

FIG. 1F illustrates a structure of the memory cells according to the first embodiment;

FIG. 1G illustrates a structure of the memory cells according to the first embodiment;

FIG. 2A is an equivalent circuit diagram of the memory cells according to the first embodiment;

FIG. 2B illustrates operating waveforms of the memory cells according to the first embodiment;

FIG. 2C illustrates operating waveforms of the memory cells according to the first embodiment;

FIG. 2D illustrates operating waveforms of the memory cells according to the first embodiment;

FIG. 2E is an equivalent circuit diagram of memory arrays according to the first embodiment;

FIGS. 3A, 3B, 3C, and FIG. 3D illustrate a related-art capacitorless dynamic flash memory cell including a MOS transistor; and

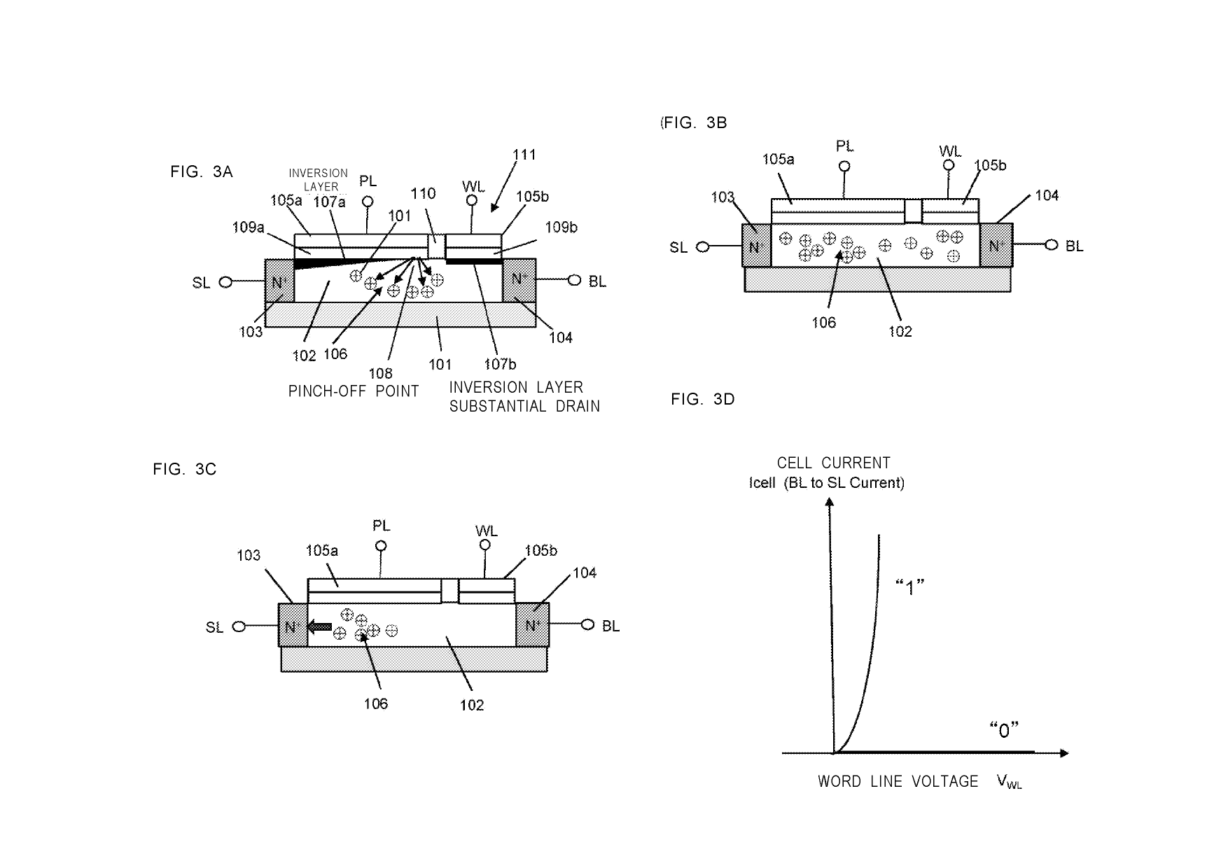

FIG. 4 illustrates a related-art capacitorless dynamic flash memory cell including a MOS transistor and three gates.

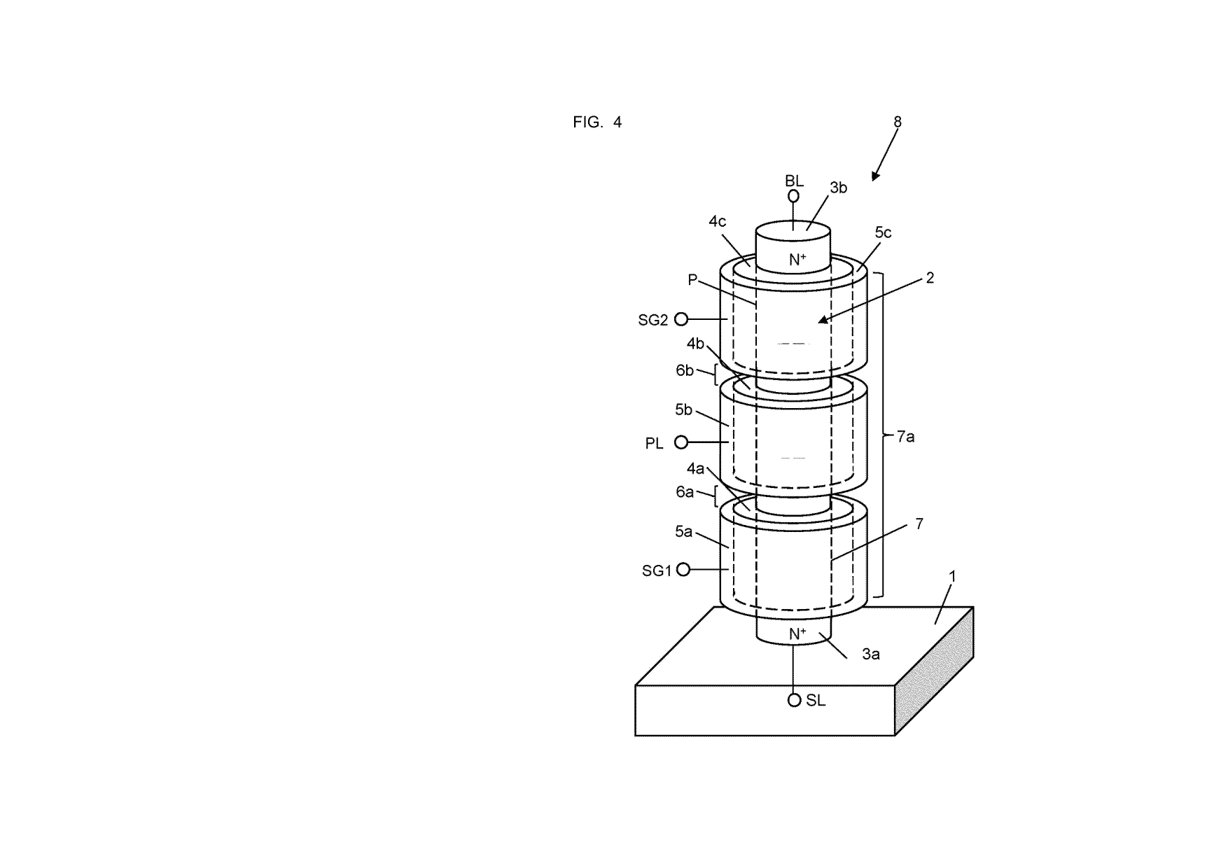

### DESCRIPTION OF THE PREFERRED EMBODIMENTS

Hereinafter, a structure and a driving method of a memory device using a semiconductor element (hereinafter, referred to as a dynamic flash memory) according to the present invention will be described with reference to the drawings.

### First Embodiment

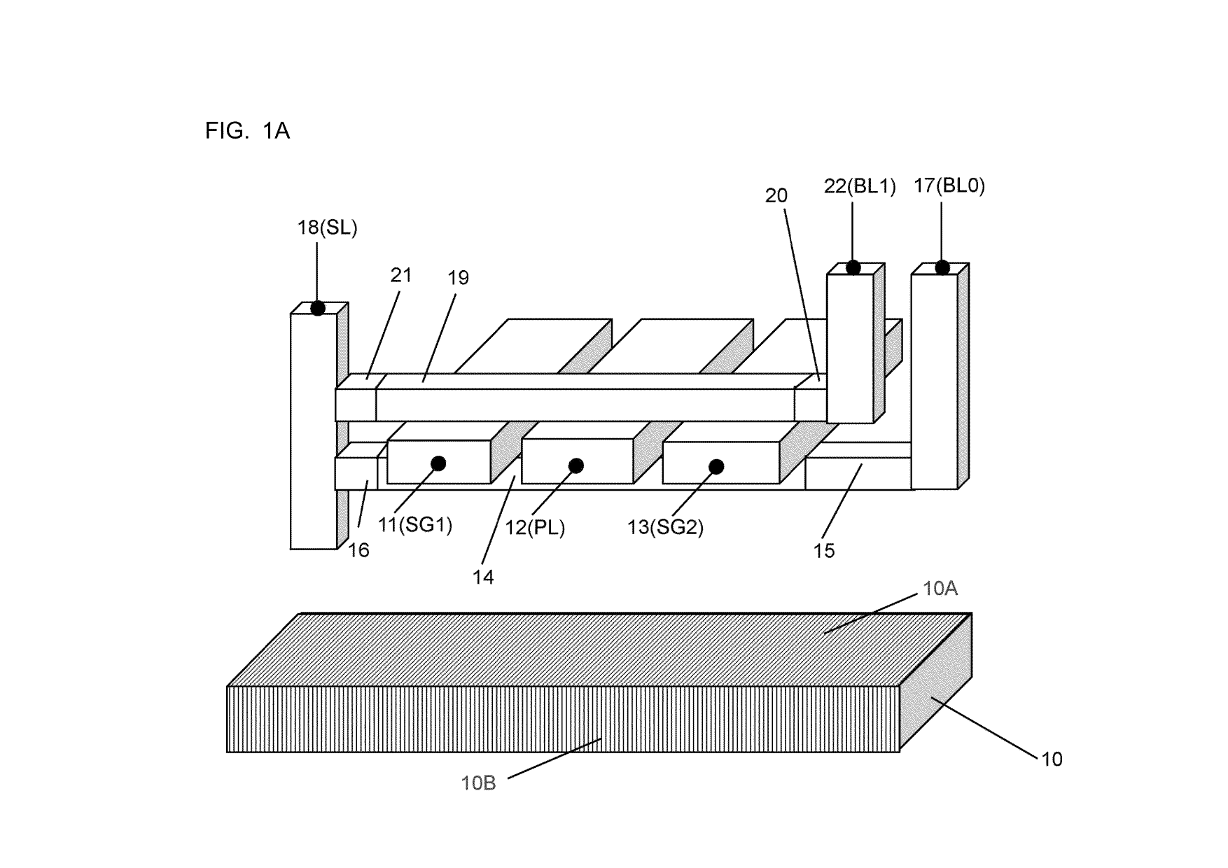

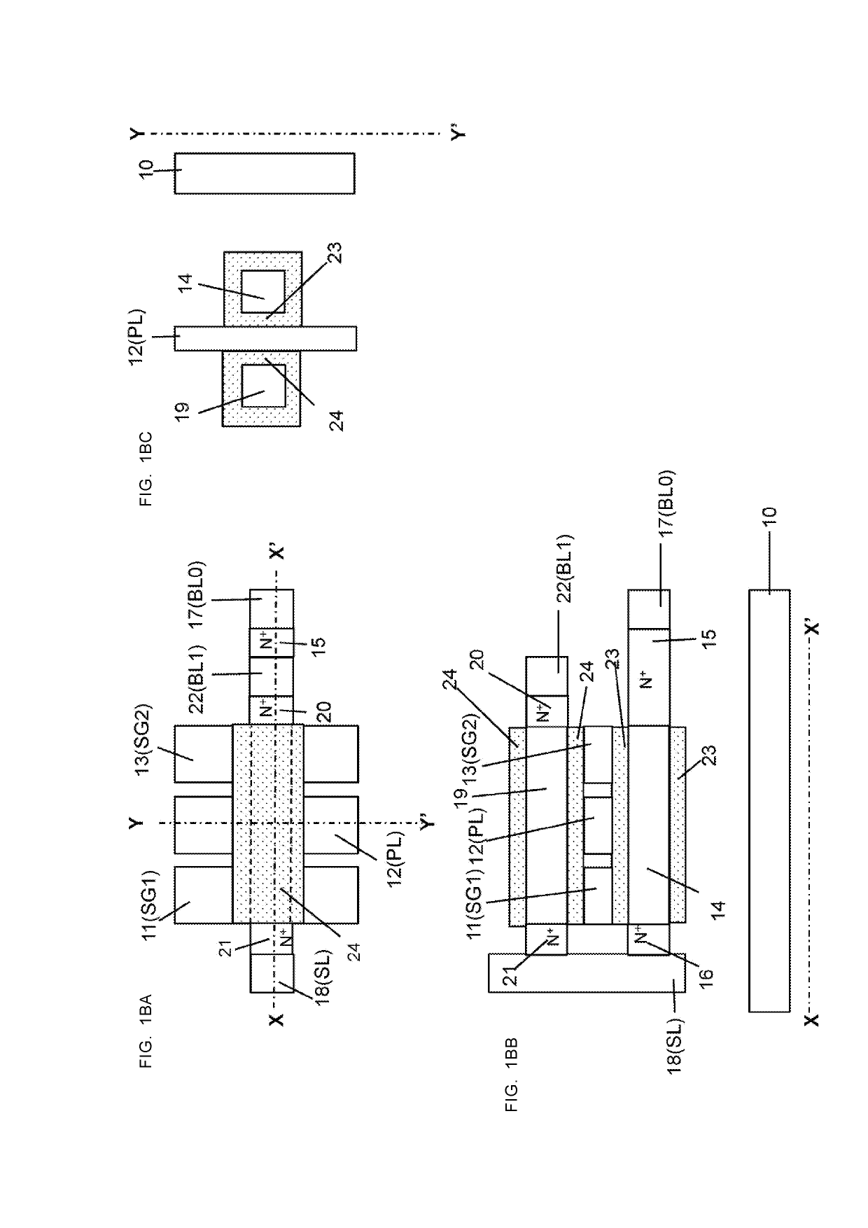

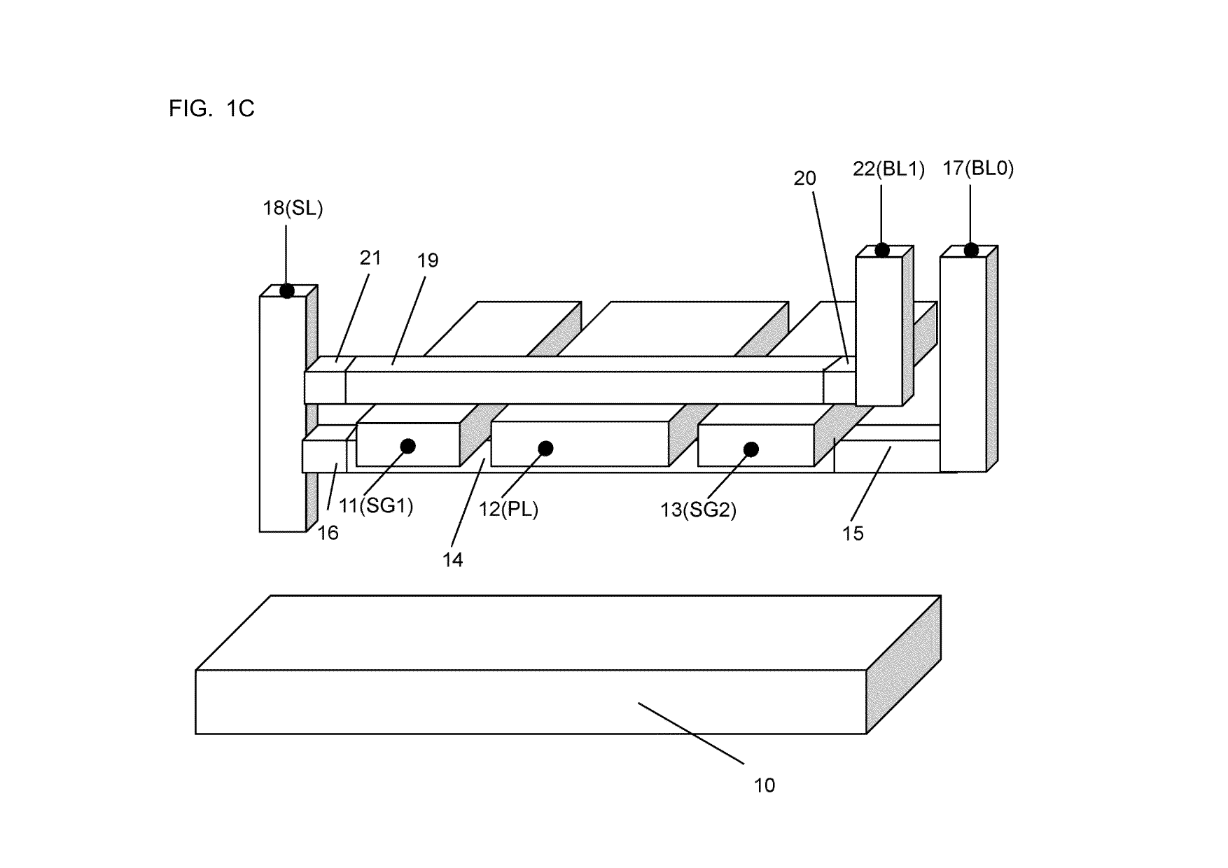

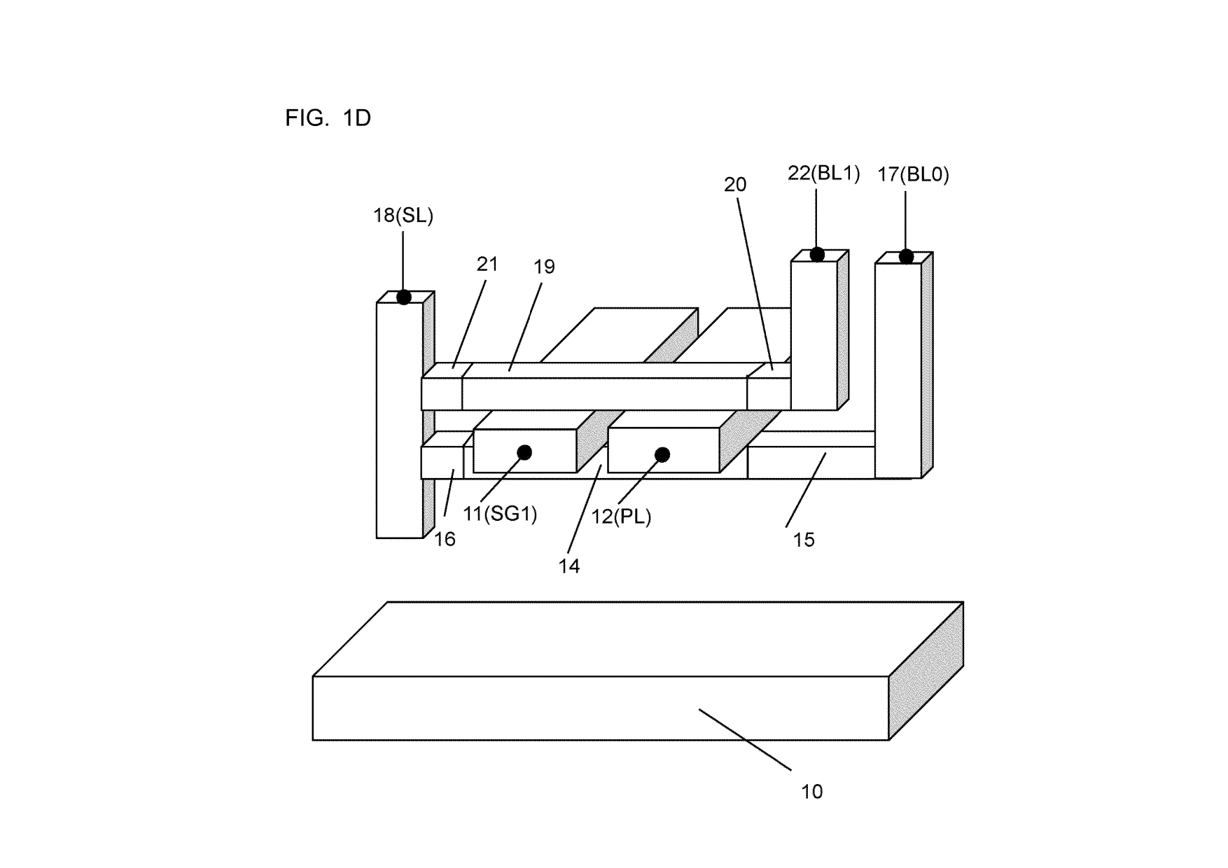

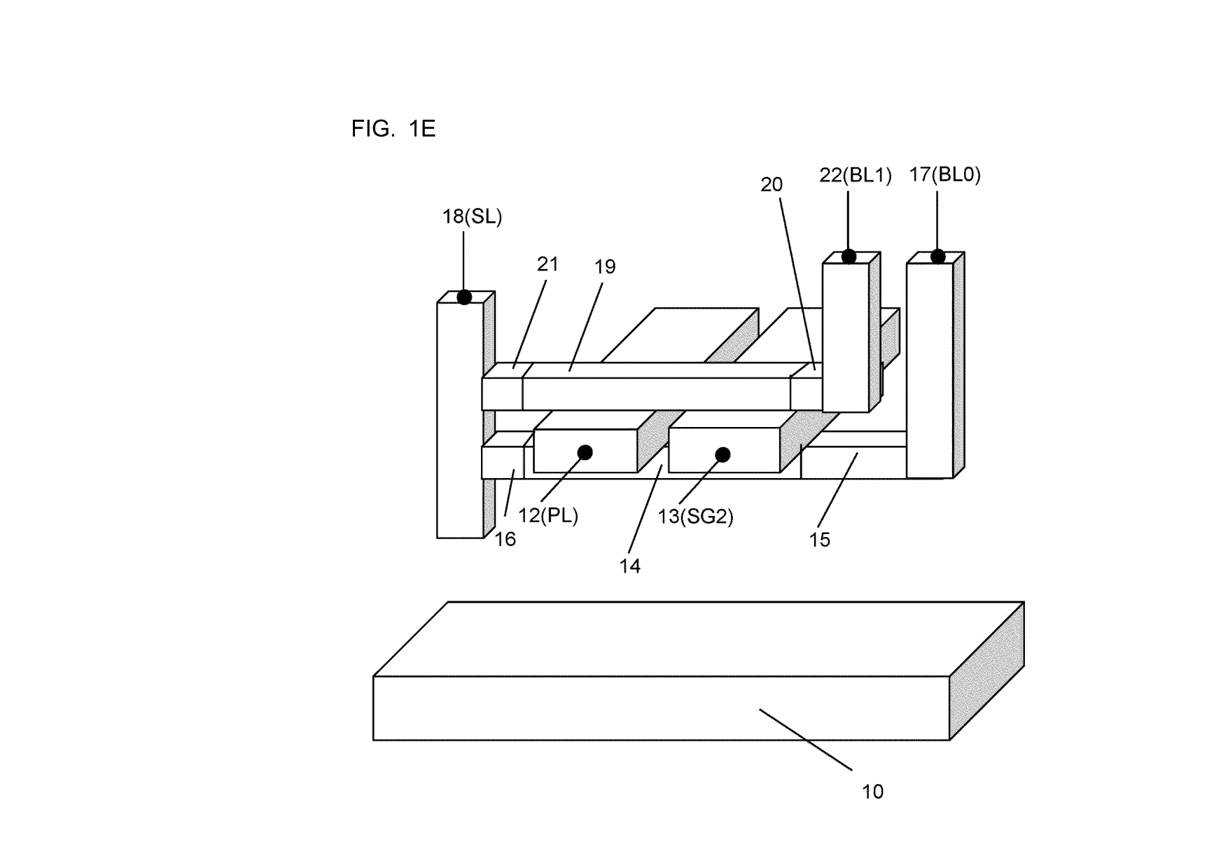

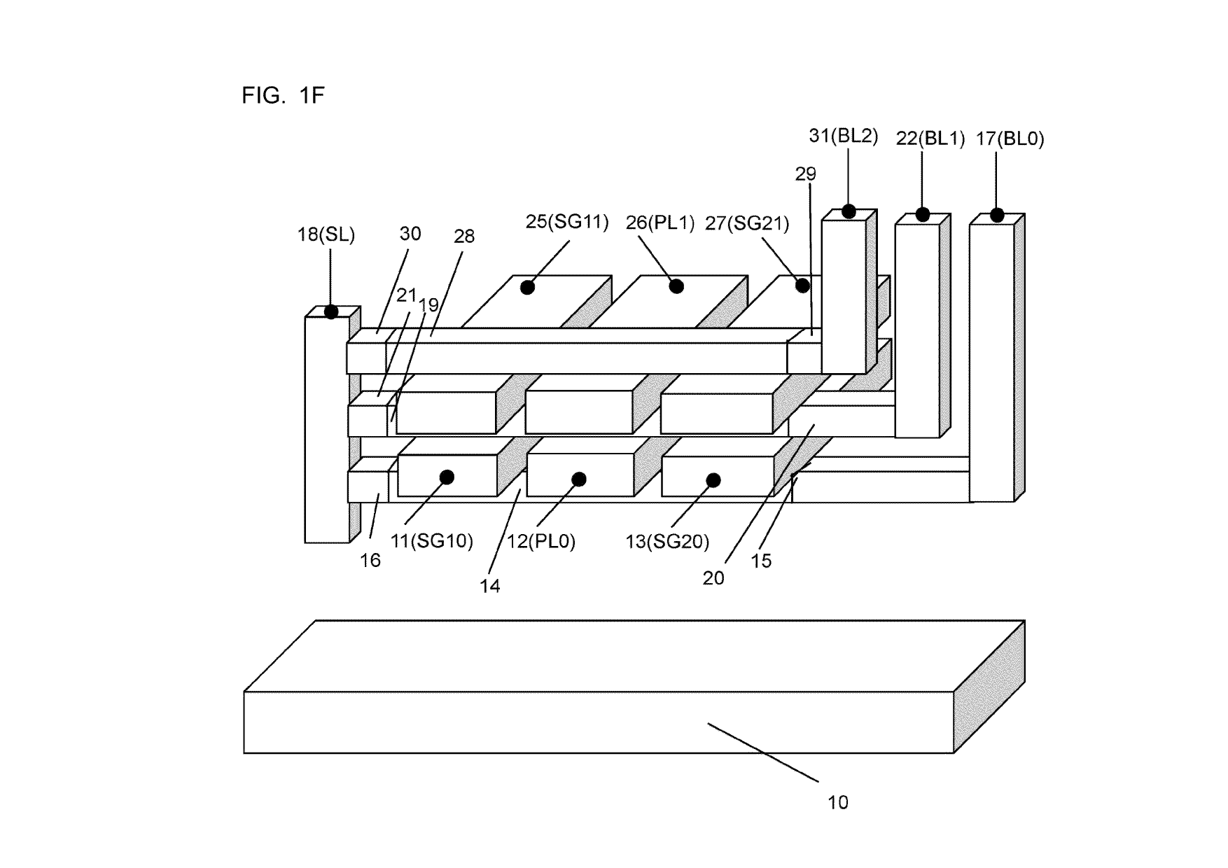

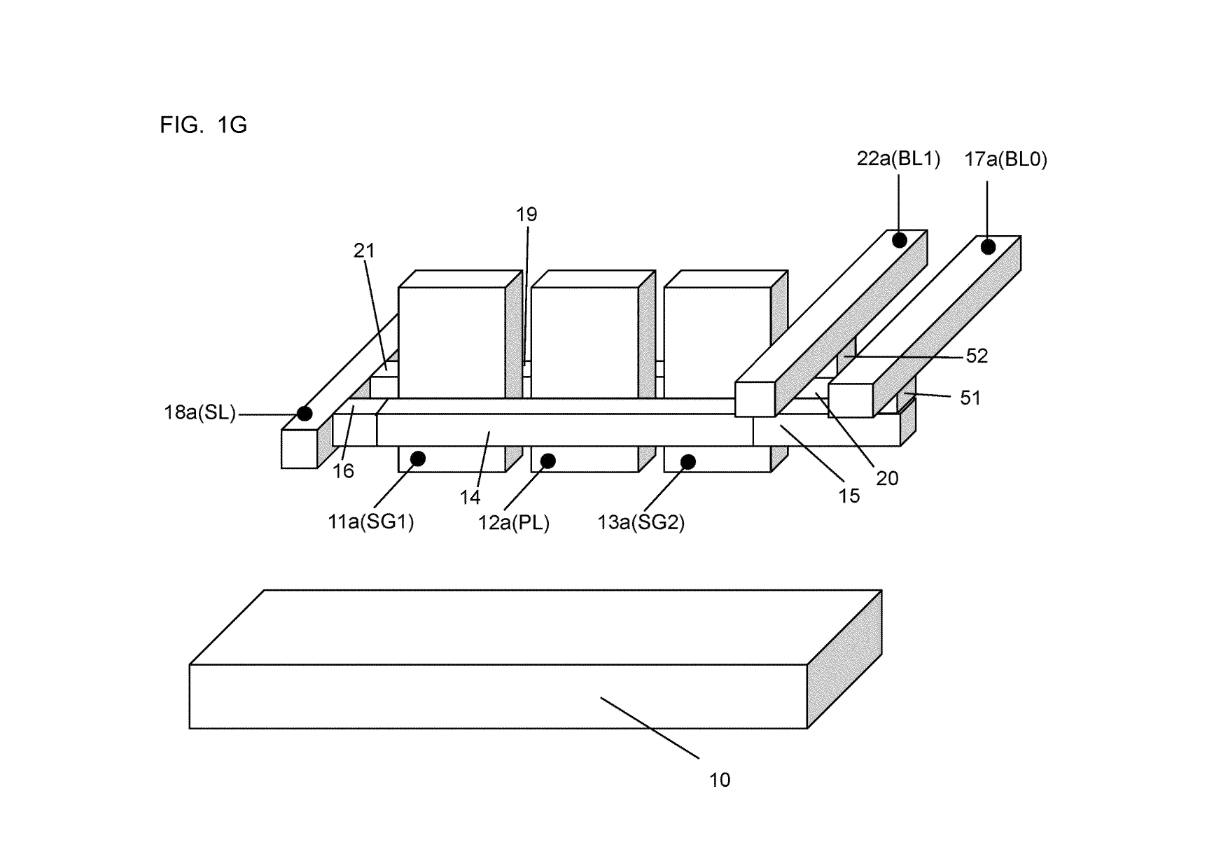

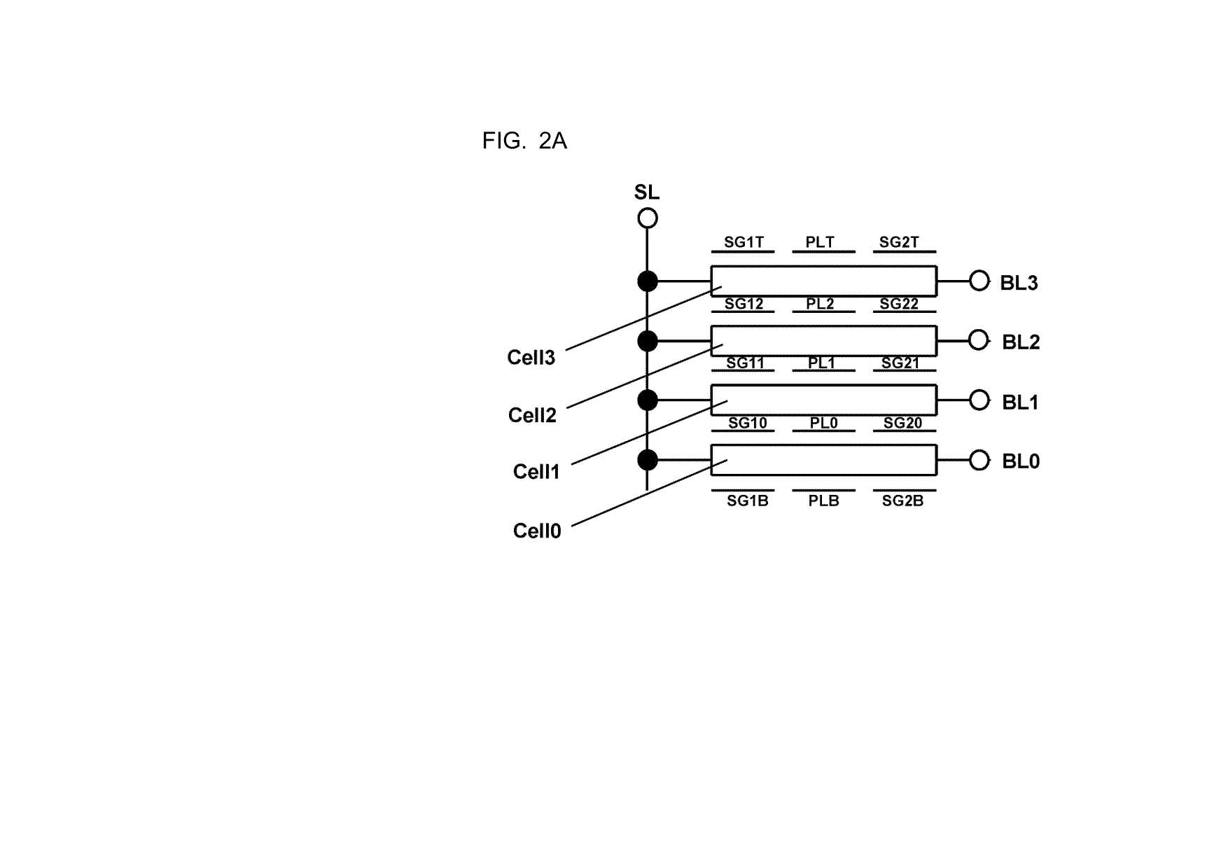

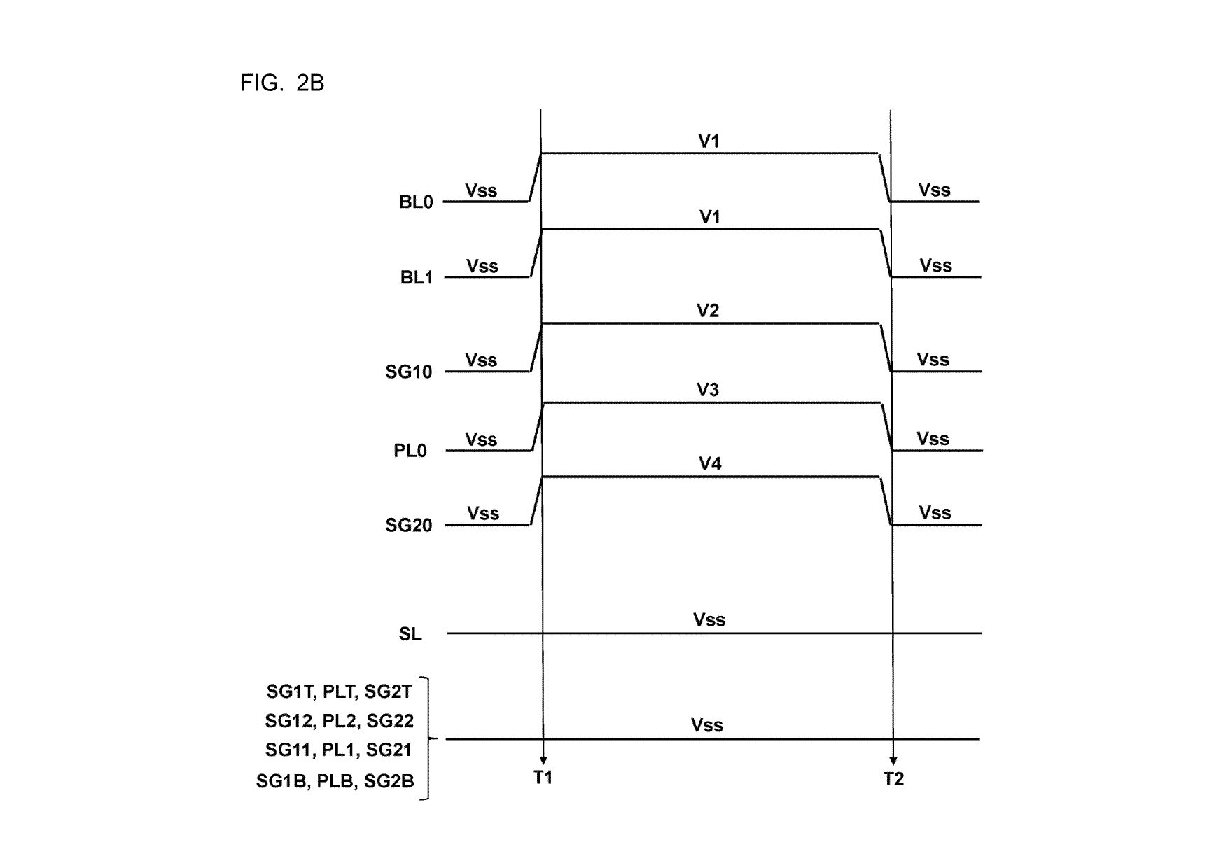

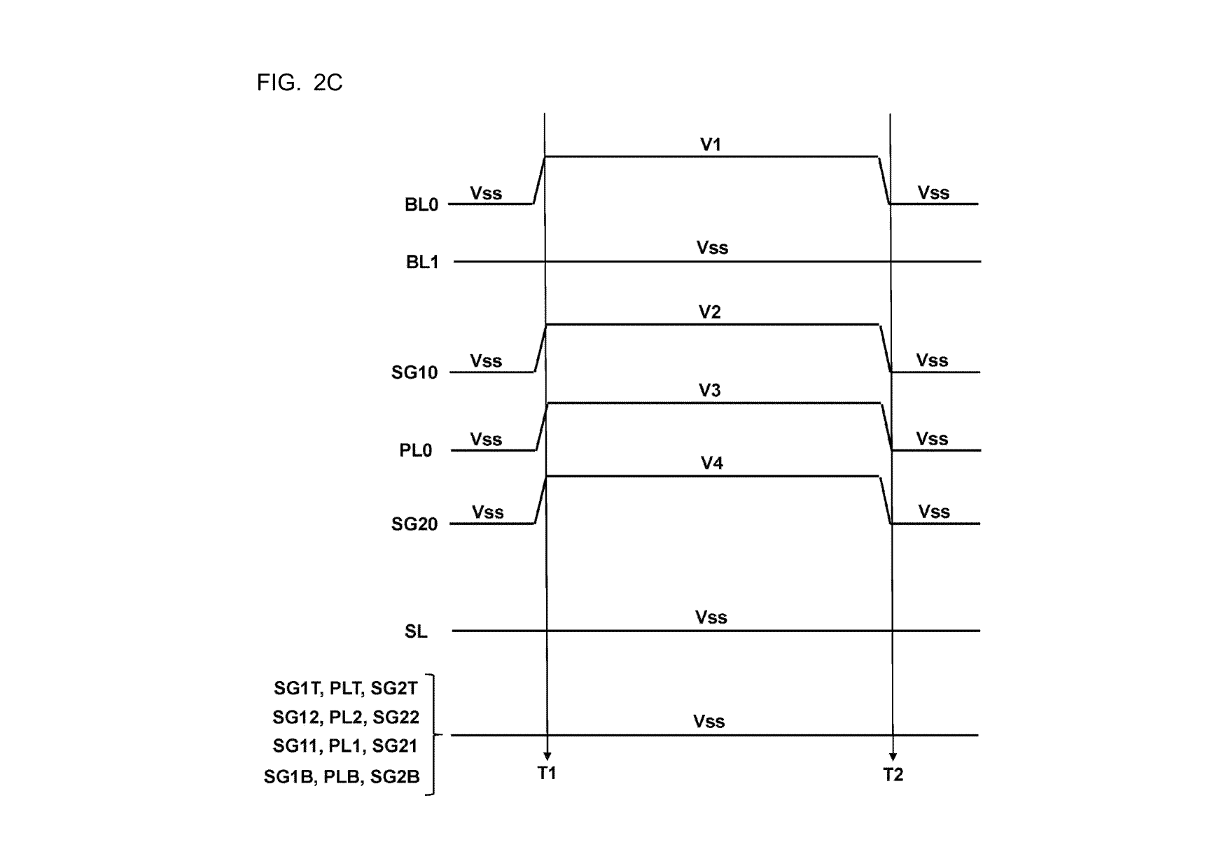

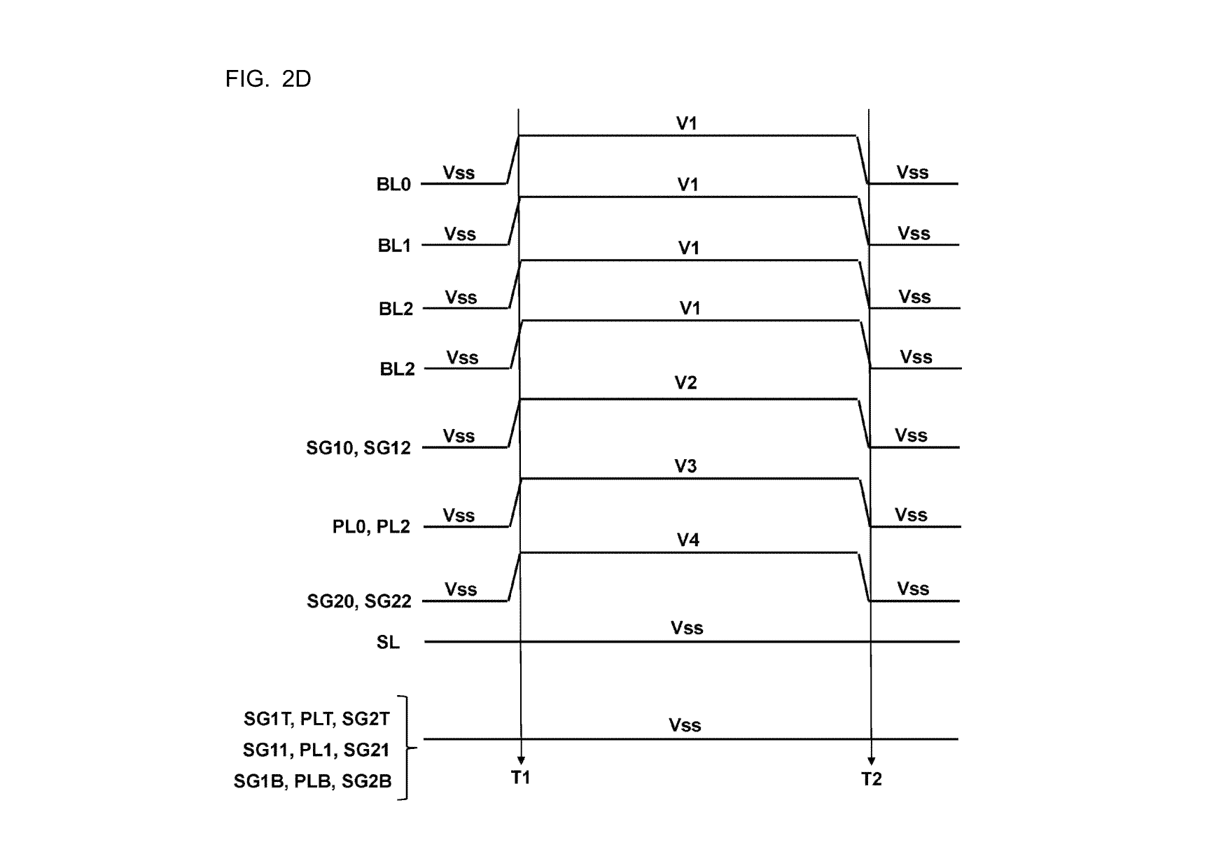

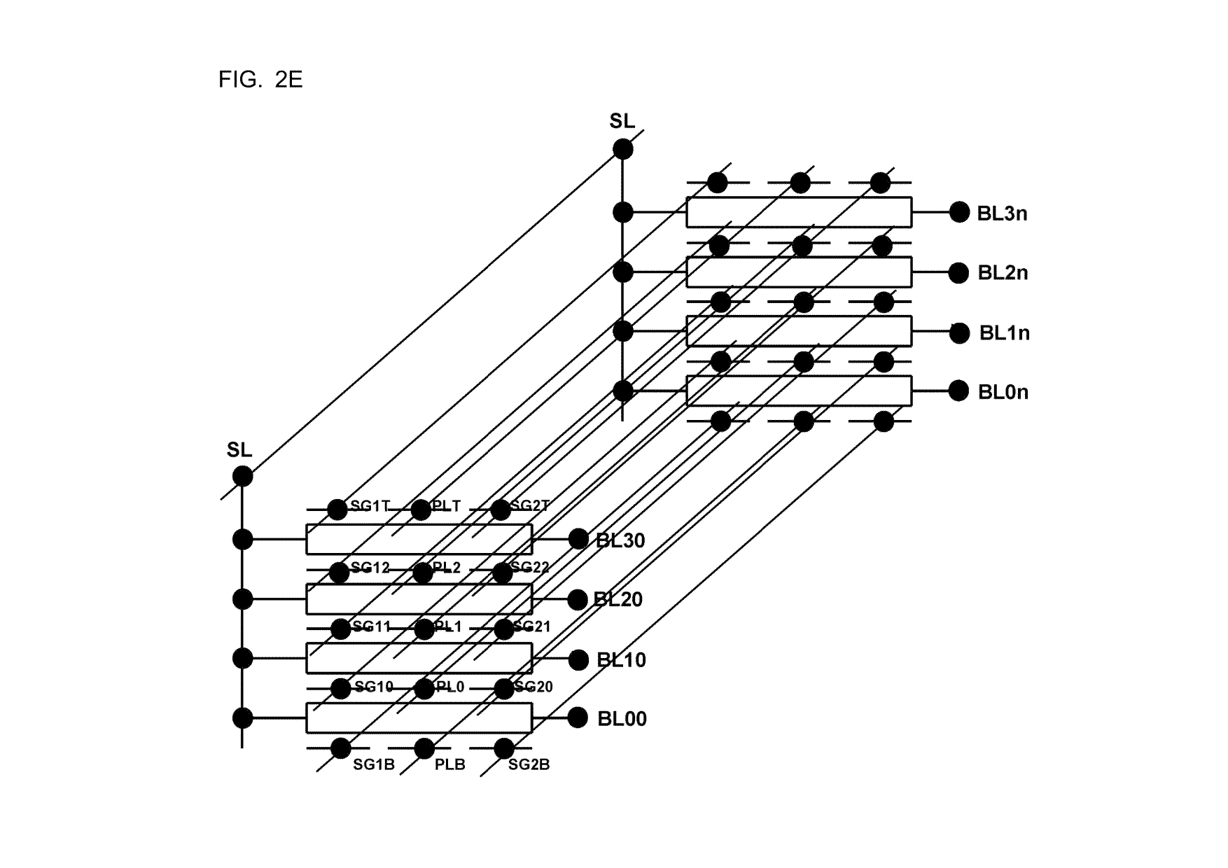

Referring to FIGS. 1A, 1BA, 1BB, 1BC, 1C, 1D, 1E, 1F, and FIG. 1G, a structure, an operation mechanism, and a manufacturing method of dynamic flash memory cells according to a first embodiment of the present invention are described. Referring to FIGS. 1A, 1BA, 1BB, and FIG. 1BC, the following structure is described: a source line 18 (SL) is disposed perpendicular to a substrate 10; and first and second selection gate lines 11 (SG1) and 13 (SG2) and a plate line 12 (PL) are disposed parallel to the substrate 10. Referring to FIG. 1G, the following structure is described: the source line 18a (SL) is disposed parallel to the substrate 10; and a second and a third selection gate lines 11a (SG1) and 13a(SG2) and a plate line 12a (PL) are disposed perpendicular to the substrate 10. Referring to FIGS. 2A, 2B, and FIG. 2C, an equivalent circuit diagram, a data write operation, a data write-protect operation, and a data read operation when four layers of the dynamic flash memory cells according to the first embodiment of the present invention are laminated in plan view 10A or in sectional view 10B illustrated in FIG. 1A with respect to the substrate 10 are described.

FIG. 1C illustrates a bird's-eye view of the structure of the dynamic flash memory cells according to the first embodiment of the present invention. FIG. 1BA illustrates a plan view of the structure of the dynamic flash memory cells according to the first embodiment of the present invention. FIG. 1BB illustrates a sectional view taken along line X-X' illustrated in FIG. 1BA. FIG. 1BC illustrates a sectional view taken along line Y-Y' illustrated in FIG. 1BA. A first semiconductor base 14 of a P layer (serving as an example of a "first semiconductor base" according to the present invention) extends in a first direction (serving as an example of a "first direction" according to the present invention) parallel to the substrate 10 (serving as an example of a "substrate" according to the present invention). U.S. Patent Application Publication No. 2022/0367681 A1 describes the structure in which the dynamic flash memory cells are provided parallel to the substrate 10. An N⁺ layer 15 (serving as an example of a "first impurity region" according to the present invention) and an N⁺ layer 16 (serving as an example of a "second impurity region" according to the present invention) are respectively provided at one end and the other end of the first semiconductor base 14. A second semiconductor base 19 of the P layer (serving as an example of a "second semiconductor base" according to the present invention), an N⁺ layer 20 (serving as an example of a "third impurity region" according to the present invention), and an N⁺ layer 21 (serving as an example of a "fourth impurity region" according to the present invention) are provided on an upper layer side of the first semiconductor base 14. A first gate insulating film 23 (serving as an example of a "first gate insulating layer" according to the present invention) and a second gate insulating film 24 (serving as an example of a "second gate insulating layer" according to the present invention) are respectively formed around the first semiconductor base 14 and the second semiconductor base 19.

A first gate conductor layer 11 (serving as an example of a "first gate conductor layer" according to the present invention), a second gate conductor layer 12 (serving as an example of a "second gate conductor layer" according to the present invention), and a third gate conductor layer 13 (serving as an example of a "third gate conductor layer" according to the present invention), which are isolated from each other, are in contact with a first side surface of the first gate insulating film 23 (serving as an example of a "first side surface" according to the present invention) and a second side surface (serving as an example of a "second side surface" according to the present invention) of the second gate insulating film 24. Although FIGS. 1A, 1BA, 1BB, 1BC, 1C, 1F, 1G, 2A, and FIG. 2B illustrate the first to third gate conductor layers as three different gate conductor layers, two gate conductor layers may be used instead. Although it will be described later, either the first gate conductor layer 11 or the third gate conductor layer 13 may be omitted as illustrated in FIGS. 1E and 1D, respectively.

The second impurity region 16 and the fourth impurity region 21 are connected to SL serving as the source line 18 (serving as an example of a "source line" according to the present invention), and the second impurity region 17 and the fourth impurity region 22 are respectively connected to BL0 serving as a first bit line 17 (serving as an example of a "first bit line" according to the present invention) and BL1 serving as a second bit line 22 (serving as an example of a "second bit line" according to the present invention). The first gate conductor layer 11 is connected to the first selection gate line SG1 (serving as an example of a "first selection gate line" according to the present invention), the second gate conductor layer 12 is connected to a plate line PL (serving as an example of a "plate line" according to the present invention), and the third gate conductor layer 13 is connected to a second selection gate line SG2 (serving as an example of a "second selection gate line" according to the present invention).

FIGS. 1A and 1G illustrate examples in which the first selection gate line includes an isolated second selection gate line and an isolated third selection gate line, one of the first gate conductor layer and the second gate conductor layer is divided into two gate conductor layers, one of the divided gate conductor layers is connected to the second selection gate line and another of the divided gate conductor layers is connected to the third selection gate line, the first gate conductor layer or the second gate conductor layer that has not been divided is connected to the plate line, and the gate conductor layer connected to the second selection gate line and the gate conductor layer connected the third selection gate line are disposed on one side and another side of the gate conductor layer connected to the plate line.

Five terminals of a first memory cell (serving as an example of a "first memory cell" according to the present invention) include the second selection gate line SG1, the plate line PL, the third selection gate line SG2, the source line SL, and the first bit line BL0. Five terminals of a second memory cell (serving as an example of a "second memory cell" according to the present invention) include the second selection gate line SG1, the plate line PL, the third selection gate line SG2, the source line SL, and the second bit line BL1.

For example, when the first memory cell is selected, the source line SL applies a ground voltage Vss, applies a positive voltage to the first bit line BL0, and controls voltages applied to the plate line PL, the second selection gate line SG1, and the third selection gate line SG2, thereby performing, on the first memory cell, the data write operation (serving as an example of a "data write operation" according to the present invention) or the data read operation (serving as an example of a "data read operation" according to the present invention).

When the second memory cell is selected, the source line SL applies the ground voltage Vss, applies a positive voltage to the second bit line BL1, and controls voltages applied to the plate line PL, the second selection gate line SG1, and the third selection gate line SG2, thereby performing, on the first memory cell, the data write operation (serving as an example of a "data write operation" according to the present invention) or the data read operation (serving as an example of a "data read operation" according to the present invention).

Accordingly, the source line SL applies the ground voltage Vss and applies a positive voltage to both the first bit line BL0 and the second bit line BL1, thereby allowing the data read operation of storage data of the first memory cell and the second memory cell to be performed on the first bit line BL0 and the second bit line BL1, respectively.

Furthermore, the positive voltage is applied to both the first bit line BL0 and the second bit line BL1, thereby allowing the data write operation to be simultaneously performed on the first memory cell and the second memory cell.

Furthermore, when, for one or both of the first memory cell and the second memory cell, a voltage that is the same voltage as the voltage of the source line SL, for example, the ground voltage Vss is applied to the first bit line BL0 and the second bit line BL1, a data write-protect operation (serving as an example of a "data write-protect operation" according to the present invention) is performed on the first memory cell and the second memory cell.

Furthermore, voltages applied to the source line SL, the first bit line BL0, the second bit line BL1, the plate line PL, the second selection gate line SG1, and the third selection gate line SG2 are controlled so as to perform a data erase operation (serving as an example of a "data erase operation" according to the present invention) on the first memory cell and the second memory cell.

Furthermore, when, for one or both of the first memory cell and the second memory cell, the voltage that is the same voltage as the voltage of the source line SL, for example, the ground voltage Vss is applied to the first bit line BL0 and the second bit line BL1, the data erase operation can be performed on one or both of the first memory cell and the second memory cell.

As illustrated in FIGS. 1BA, 1BB, and FIG. 1BC, the first to third gate conductor layers 11, 12, and 13 serve as common gate conductor layers to the two dynamic flash memory cells that use the first semiconductor base 14 and the second semiconductor base 19 as channels. It is sufficient that the first gate insulating film 23 be provided at least between the first to third gate conductor layers 11, 12, and 13 and the first semiconductor base 14. Likewise, it is sufficient that the second gate insulating film 24 be provided at least between the first to third gate conductor layers 11, 12, and 13 and the second semiconductor base 19.

FIG. 1A illustrates a case where a channel length (length in the line X-X' direction) of the plate line PL is set to be the same as channel lengths of the selection gate line SG1 and the selection gate line SG2. In contrast, as illustrated in FIG. 1C, the channel length (lengths in the line X-X' direction) of the plate line PL may be set to be greater than the channel lengths of the selection gate line SG1 and the selection gate line SG2. In this way, a good controllability of a plate line voltage is obtained for floating bodies of the memory cells. Furthermore, depending on the channel length (gate length) of the plate line, more positive holes can be held in a floating body in a "1" write state.

FIG. 1D illustrates an example in which the second selection gate line SG1 adjacent to the first source line SL is removed. That is, this structure includes the third selection gate line SG2 that is the first selection gate line (serving as an example of the "first selection gate line" according to the present invention) not divided and the plate line PL. FIG. 1E illustrates an example in which the third selection gate line SG2 adjacent to bit lines BL0 and BL1 is removed. That is, this structure includes the second selection gate line SG1 that is the first selection gate line not divided and the plate line PL. In this way, a cell size of the dynamic flash memory cell can be further miniaturized. Furthermore, a cell current can be increased, and the speed can be further increased. Although there is a drawback of reducing a data retention capability due to removal of one of the selection gates, the good controllability of the plate line voltage is obtained for the floating bodies of the memory cells. Furthermore, depending on the gate length of the plate line, more positive holes can be held in the floating body in the "1" write state. Which structure to use can be selected depending on application in which the dynamic flash memory cells are used.

FIG. 1F illustrates an example in which three dynamic flash memory cells are laminated. A third semiconductor base 28 is provided above the second semiconductor base 19. A first gate conductor layer 25 connected to a selection gate line SG11, a second gate conductor layer 26 connected to a plate line PL1, and a third gate conductor layer 27 connected to a selection gate line SG21 are provided between the second semiconductor base 19 and the third semiconductor base 28. N⁺ layers 29 and 30 are provided at one end and the other end of the third semiconductor base 28. The N⁺ layer 29 is continuous with a third bit line 31 (BL2), the N⁺ layer 20 is continuous with the second bit line 22 (BL1), and the N⁺ layer 15 is continuous with the first bit line 17 (BL0). The N⁺ layer 18 is continuous with the source line 18 (SL).

FIG. 1G illustrates an example in which the second selection gate line SG1, the plate line PL, the third selection gate line SG2, a first bit line 17a (BL0), and a second bit line 22a (BL1) are disposed perpendicular to the substrate 10, and the source line SL is disposed parallel to the substrate 10. That is, the dynamic flash memory cells illustrated in FIG. 1G correspond to dynamic flash memory cells obtained by rotating the dynamic flash memory cells illustrated in FIGS. 1A, 1BA, 1BB, 1BC, 1C, 1D, 1E, and FIG. 1F by 90 degrees toward a depth direction of the pages of the drawings relative to the substrate 10. Although any of the dynamic flash memory cells can be selected depending on the application in which the dynamic flash memory cells are used, main features of the dynamic flash memory cells illustrated in FIG. 1G are the same as those of the dynamic flash memory cells illustrated in FIGS. 1A, 1BA, 1BB, 1BC, 1C, 1D, 1E, and FIG. 1F. The first bit line 17a (BL0) and the second bit line 22a (BL1) are respectively in contact with the N⁺ layer 15 and the N⁺ layer 20 at a first via contact 51 and a second via contact 52.

FIG. 2A illustrates an equivalent circuit diagram when four memory cells Cell 0 to Cell 3 of the dynamic flash memory cells according to the first embodiment of the present invention are laminated with respect to the substrate in plan view or in sectional view. FIG. 2B illustrates operating waveforms of the data write operation and the data read operation of the four memory cells Cell 0 to Cell 3. At a first time T1, voltages of the first bit line BL0, the second bit line BL1, the second selection gate line SG10, the plate line PL0, and the third selection gate line SG20 are respectively changed from the ground voltage Vss to a first voltage V1, the first voltage V1, a second voltage V2, a third voltage V3, a fourth voltage V4, and the voltage of the source line SL is set to the ground voltage Vss. As a result, the first memory cell Cell 0 and the second memory cell Cell 1 are selected and the data write operation or the data read operation is performed on the first memory cell Cell 0 and the second memory cell Cell 1.

Furthermore, when the ground voltage Vss that is the same voltage as the voltage of the source line SL is applied to the second bit line BL1 in the second memory cell Cell 1 in FIG. 2C, the data write-protect operation is performed on the second memory cell Cell 1 while the data write operation is performed on the first memory cell Cell 0. Alternatively, when the data read operation is performed on the first memory cell Cell 0, the data read operation is not performed on the second memory cell Cell 1. That is, the data write operation or the data read operation is performed on either the first bit line BL0 or the second bit line BL1.

Referring to FIG. 2B, when the data write operation or the data read operation is performed on the first memory cell Cell 0 and the second memory cell Cell 1, SG1B, PLB, SG2B, SG11, PL1, and SG21 are set to be Vss. As a result, side surfaces facing SG10, PL0, SG20 of the semiconductor base of the P layer of the first memory cell Cell 0 and side surfaces facing SG10, PL0, SG20 of the semiconductor base of the P layer of the second memory cell Cell 1 are set to be Vss and shielded. Accordingly, positive hole groups of the first and second semiconductor bases of the P layers of the first memory cell Cell 0 and the second memory cell Cell 1 are collected to these shielded side surfaces. This allows the data write operation or the data read operation to be performed with higher stability and higher reliability.

Vss may be zero volt, any negative voltage, or any positive voltage.

FIG. 2D illustrates a case where the data write operation or the data read operation is performed simultaneously on the first memory cell Cell 0 to the fourth memory cell Cell 3. The first bit line BL0 to the fourth bit line BL3 are changed from Vss to V1, the gate lines SG10, PL0, SG20 and SG12, PL2, SG22 of two sets of the gate lines are respectively changed from Vss to V2, V3, and V4. Furthermore, SG1B, PLB, SG2B, SG11, PL1, SG21, SG1T, PLT, and SG2T are set to be Vss. Thus, since the data write operation or the data read operation can be performed on the four bit lines, that is, first to fourth bit lines BL0 to BL3, data throughput can be quadrupled, and the operation speed can also be quadrupled.

FIG. 2E illustrates a bird's-eye view in which a bit line array of the equivalent circuit diagram illustrated in FIG. 2A is increased from BL0n to BL3n in the depth direction. For example, when n in BL0n to BL3n is 1023, the number of the bit line arrays of four layers is 1024. The data write operation from a sense amplifier circuit (not illustrated) to these bit line arrays is simultaneously performed, or the data read operation from these bit line arrays to the sense amplifier circuit is simultaneously performed.

The dynamic flash memory cells illustrated in FIGS. 1A, 1BA, 1BB, 1BC, 1C, 1D, 1E, 1F, 1G, 2A, 2B, 2C, 2D, and FIG. 2E have been described using the shapes in which the configurational items have rectangular vertical sections. However, these vertical sectional shapes may be other shapes such as, for example, trapezoidal shapes. Furthermore, the different elements may have different vertical sections. These are applied to the other embodiments in the same manner.

Furthermore, also in a structure in which the conductivities of the semiconductor bases of the N⁺ layers 15, 16, 20, and 21 and the P layers 14 and 19 of the dynamic flash memory cells illustrated in FIGS. 1A, 1BA, 1BB and 1BC are reversed, the operations of the dynamic flash memory are performed. In this case, in the semiconductor base of the N type, the majority carrier is electrons. Accordingly, an electron group generated due to impact ionization is stored in the floating body, and a "1" state is set. Furthermore, a dynamic flash memory cells using a P-type semiconductor base and an N-type semiconductor base may be formed on the same substrate. These are applied to the other embodiments in the same manner.

Furthermore, a junctionless structure may be used. In the junctionless structure, the conductivities of the semiconductor bases of the N⁺ layers 15, 16, 20, and 21 and the P layers 14 and 19 of the dynamic flash memory cells illustrated in FIGS. 1A, 1BA, 1BB and 1BC are the same. This is applied to the other embodiments in the same manner.

Furthermore, the dynamic flash memory cells illustrated in FIGS. 1A, 1BA, 1BB, 1BC, 1C, 1D, 1E, 1F, 1G, 2A, 2B, 2C, 2D, and FIG. 2E may be arranged in a matrix shape on the substrate and form memory blocks. In this case, a plurality of memory blocks are selected when at least one of the data write operation, the data erase operation, and the data read operation is performed. As a result, the number of memory cells selected in the plurality of memory blocks increases, and accordingly, the data writing time per cell, data erasing time per cell, and data read time per cell can be further reduced.

### Features

The present embodiment has the following features. According to the embodiment of the present invention, two laminated memory cells in the dynamic flash memory cells share the second selection gate line SG1, the plate line PL, and the third selection gate line SG2. This reduces the aspect ratio of the plurality of laminated memory cells. Thus, the number of the memory cells able to be laminated can be further increased, and the reduction of the cost can be achieved. This is similarly applied to the memory cells illustrated in FIGS. 1C, 1D, 1E, 1F, 1G, 2A, 2B, and FIG. 2C. The first bit line BL0 and the second bit line BL1 of two laminated memory cells Cell 0 and Cell 1 are isolated from each other. Thus, the data write operation or the data read operation can be simultaneously performed on the memory cells connected to the first bit line BL0 and the second bit line BL1. As a result, the data throughput can be doubled, and the operation speed can also be doubled. Furthermore, between the first bit line BL0 and the second bit line BL1, it is possible to perform the data write-protect operation on one of the memory cells while performing the data write operation on the other memory cell, or to refrain from performing the data read operation on one of the memory cells while performing the data read operation on the other memory cell. Thus, instructions requested by the system can be more flexibly handled.

### Other Embodiments

The gate conductor layer continuous with the plate line may be a single layer or a combination of a plurality of conductor material layers. Likewise, the gate conductor layers continuous with the second selection gate line and the third selection gate line may be a single layer or a combination of a plurality of conductor material layers. Furthermore, an outer side of the gate conductor layer may be continuous with a wiring metal layer of, for example, W or the like. These are similarly applied to the other embodiments according to the present invention.

Furthermore, as the voltage of the plate line PL in the description of the embodiment, for example, a fixed voltage of 0 V may be applied regardless of the operation modes. As the voltage of the plate line PL, a fixed voltage or a time-varying voltage may be applied as long as the voltage to be applied satisfies the conditions under which the operations of the dynamic flash memory can be performed.

Furthermore, referring to FIGS. 1A, 1BA, 1BB, 1BC, 1C, 1D, 1E, 1F, and FIG. 1G, an N-type or P-type impurity region may be provided between the first impurity region N⁺ layer 15 and/or the second impurity region N⁺ layer 16 and the first semiconductor base P layer 14. This is similarly applied to the other embodiments according to the present invention.

Furthermore, according to the description, the positive hole group being a majority carrier is generated by the impact ionization. However, for example, the positive hole group may be generated by a different method such as a gate induced drain leakage current (GIDL current).

Furthermore, in the data read operation, the data read operation may be performed by a different method such as a bipolar operation.

In addition, various embodiments and modifications of the present invention can be made without departing from the broad spirit and scope of the present invention. Each of the embodiments described above is provided for describing an example of the present invention and does not limit the scope of the present invention. The above-described examples and modifications may be combined with each other in any combination. Furthermore, embodiments in which a subset of constituent elements of the above-described embodiment is omitted as necessary also fall within the scope of the technical thought of the present invention.

With the memory device using the semiconductor element according to the present invention, high-density high-performance dynamic flash memory can be obtained.

What is claimed is:

1. A memory device using a semiconductor element,
wherein a plurality of semiconductor memory cells including a first memory cell and a second memory cell are arranged on a substrate,
the first memory cell includes
a first semiconductor base extending in a first direction parallel to the substrate,
the second memory cell includes
a second semiconductor base separated from the first semiconductor base in a vertical direction or a horizontal direction, the second semiconductor base overlapping the first semiconductor base in plan view when the second semiconductor base is separated from the first semiconductor base in the vertical direction, the second semiconductor base being at a position overlapping the first semiconductor base in sectional view when the second semiconductor base is separated from the first semiconductor base in the horizontal direction,
wherein the memory device includes
a first impurity region and a second impurity region respectively continuous with one end and another end of the first semiconductor base,
a third impurity region and a fourth impurity region respectively continuous with one end and another end of the second semiconductor base,
a first gate insulating layer in contact with a first side surface out of side surfaces of the first semiconductor base facing the second semiconductor base,
a second gate insulating layer in contact with a second side surface out of side surfaces of the second semiconductor base facing the first semiconductor base, and
one or two first gate conductor layers and one or two second gate conductor layers, each of the first gate conductor layers and each of the second gate conductor layers being in contact with the first and second gate insulating layers so as to function as the gate conductor layers common to the first memory cell and second memory cell, the first gate conductor layers and the second gate conductor layers being arranged in the first direction and isolated from each other,
wherein, the first to fourth impurity regions and the first and second gate conductor layers are configured such that, when the memory device is controlled so as to apply a voltage to the first to fourth impurity regions and the first and second gate conductor layers,
a data write operation that, in one or both of the first semiconductor base and the second semiconductor base, causes a part or an entirety of a positive hole group or an electron group serving as a majority carrier to remain in one or both of the first semiconductor base and the second semiconductor base,
a data write-protect operation that, during the data write operation, prohibits remaining of the part or the entirety of the positive hole group or the electron group in another or both of the first semiconductor base and the second semiconductor base,
a data erase operation that discharges the remaining positive hole group or the remaining electron group from one or both of the first and second impurity regions and one or both of the third and fourth impurity regions, and
a data read operation causing, by using storage data of a data write state or a data erase state in one of the first semiconductor base and the second semiconductor base, a current to flow through the first semiconductor base or the second semiconductor base or prohibiting flowing of the current through the first semiconductor base or the second semiconductor base are performed, and
wherein the second impurity region is connected to a first bit line, the fourth impurity region is connected to a second bit line, and the first and third impurity regions are connected to a source line.

2. The memory device according to claim 1,
wherein one of the first gate conductor layer and the second gate conductor layer is connected to a first selection gate line and another of the first gate conductor layer and the second gate conductor layer is connected to a plate line, and
wherein, when the memory device is controlled so as to apply the voltage to the first and second bit lines, the source line, the plate line, and the first selection gate line, the data erase operation, the data write operation, and the data read operation are performed.

3. The memory device according to claim 2,
wherein, in the data write-protect operation, the voltage applied to the first or second bit line and the voltage applied to the source line are identical to each other.

4. The memory device according to claim 1,
wherein the data read operation on the first memory cell connected to the first bit line and the data read operation on the second memory cell connected to the second bit line are performed simultaneously or alternately.

5. The memory device according to claim 2,
wherein the first and second semiconductor bases overlap each other in sectional view of the substrate, and the plate line and the first selection gate line are disposed parallel to the substrate such that the plate line and the first selection gate line are perpendicular to the substrate in plan view.

6. The memory device according to claim 2,
wherein the first and second bit lines are disposed perpendicular to the plate line and the first selection gate line in perpendicular sectional view with respect to the substrate.

7. The memory device according to claim 2,
wherein the first and second semiconductor bases overlap each other in plan view of the substrate, and the plate line and the first selection gate line are disposed parallel to the substrate such that the plate line and the first selection gate line are perpendicular to the substrate in sectional view.

8. The memory device according to claim 2,
wherein the first and second bit lines are disposed perpendicular to the plate line and the first selection gate line in plan view with respect to the substrate.

9. The memory device according to claim 2,
wherein the first selection gate line includes an isolated second selection gate line and an isolated third selection gate line,
wherein one of the first gate conductor layer and the second gate conductor layer is divided into two gate conductor layers,
wherein one of the divided gate conductor layers is connected to the second selection gate line and another of the divided gate conductor layers is connected to the third selection gate line,
wherein the first gate conductor layer or the second gate conductor layer that has not been divided is connected to the plate line, and
wherein the gate conductor layer connected to the second selection gate line and the gate conductor layer connected the third selection gate line are disposed on one side and another side of the gate conductor layer connected to the plate line.

10. The memory device according to claim 9,
wherein a channel length of the gate conductor layer connected to the plate line is greater than a channel length of the gate conductor layer connected to the second selection gate line and a channel length of the gate conductor layer connected to the third selection gate line.

11. The memory device according to claim 1,
wherein the plurality of semiconductor memory cells are arranged in a matrix shape on the substrate to form memory blocks, and a plurality of the memory blocks are selected when at least one of the data write operation, the data erase operation, and the data read operation is performed.

12. The memory device according to claim 1,
wherein, when the data write operation or the data read operation is performed in the first semiconductor base, the part or the entirety of the positive hole group or the electron group serving as the majority carrier is collected to the side surface of one of the first gate insulating layer side or the second gate insulating layer side.

13. The memory device according to claim 1,
wherein the first to fourth impurity regions and the first and second gate conductor layers are configured such that
the data write operation that causes the part or the entirety of the positive hole group or the electron group serving as the majority carrier to remain in the first or second semiconductor base, the positive hole group or the electron group being generated by impact ionization due to a current flowed through the one of the first and second semiconductor bases or a gate induced drain leakage current,
the data write-protect operation that does not cause the impact ionization or does not allow flowing of the gate induced drain leakage current in another of the first and second semiconductor bases during the data write operation so as to prohibit remaining of the part or the entirety of the positive hole group or the electron group serving as the majority carrier in the first or second semiconductor base,
the data erase operation that discharges the remaining positive hole group or the remaining electron group from one or both of the first and second impurity regions and one or both of the third and fourth impurity regions, and
the data read operation that, by using the storage data of the data write state or the data erase state of one of the first and second semiconductor bases, causes the current to flow through the first or second semiconductor base or prohibits flowing of the current through the first or second semiconductor base are performed.
